(19) United States
(12) Patent Application Publication
(10) Pub. No.: US 2025/0234687 A1
(43) Pub. Date: Jul. 17, 2025

(54) SEMICONDUCTOR CHIP

(71) Applicant: Innolux Corporation, Miaoli County (TW)

(72) Inventors: Shu-Ming Kuo, Miaoli County (TW); Tsau-Hua Hsieh, Miaoli County (TW); Jian-Jung Shih, Miaoli County (TW)

(73) Assignee: Innolux Corporation, Miaoli County (TW)

(21) Appl. No.: 18/988,740

(22) Filed: Dec. 19, 2024

Related U.S. Application Data
(60) Provisional application No. 63/620,895, filed on Jan. 15, 2024.

(30) Foreign Application Priority Data
Oct. 14, 2024 (CN) 202411432681.9

(51) Int. Cl. H10H 20/853; H10H 20/856

(52) U.S. Cl. CPC H10H 20/853; H10H 20/856

(57) ABSTRACT

A semiconductor chip includes a semiconductor die, a filling layer, a first electrode, a second electrode, and a reflective layer. The semiconductor die includes a first type semiconductor layer, an active layer, and a second type semiconductor layer stacked in sequence. The filling layer surrounds the semiconductor die. The first electrode is disposed on a first side of the semiconductor die and electrically connected to the first type semiconductor layer. The second electrode is disposed on a second side of the semiconductor die and electrically connected to the second type semiconductor layer. In a top view, a first virtual line segment crossing a center of the semiconductor die intersects with an edge of the filling layer at a first point and a second point. A distance between the center and the first point is different from a distance between the center and the second point.

### CROSS-REFERENCE TO RELATED APPLICATION

This application claims the priority benefit of U.S. provisional application Ser. No. 63/620,895, filed on Jan. 15, 2024, and China application serial no. 202411432681.9, filed on Oct. 14, 2024. The entirety of each of the above-mentioned patent applications is hereby incorporated by reference herein and made a part of this specification.

### BACKGROUND

### Technical Field

The disclosure relates to a semiconductor chip, particularly to a semiconductor chip that may change the light emission pattern.

### Description of Related Art

The electronic device or the splicing electronic device is widely applied in different fields such as communication, display, automotive, or aviation. With the rapid development of the electronic device, the electronic device is developing to become lighter and thinner, so the reliability or quality requirement for the electronic device is becoming higher.

### SUMMARY

The disclosure provides a semiconductor chip that may change the light emission pattern.

According to an embodiment of the disclosure, the semiconductor chip includes a semiconductor die, a filling layer, a first electrode, a second electrode, and a reflective layer. The semiconductor die includes a first type semiconductor layer, an active layer, and a second type semiconductor layer stacked in sequence. The filling layer surrounds the semiconductor die. The first electrode is disposed on a first side of the semiconductor die and electrically connected to the first type semiconductor layer. The second electrode is disposed on a second side of the semiconductor die and electrically connected to the second type semiconductor layer. The reflective layer is disposed on the filling layer. In a top view, a first virtual line segment crossing a center of the semiconductor die intersects with an edge of the filling layer at a first point and a second point. A distance between the center of the semiconductor die and the first point is different from the distance between the center of the semiconductor die and the second point.

According to an embodiment of the disclosure, the semiconductor chip includes a semiconductor die, a filling layer, a first electrode, a second electrode, and a reflective layer. The semiconductor die includes a first type semiconductor layer, an active layer, and a second type semiconductor layer stacked in sequence. The filling layer surrounds the semiconductor die. The first electrode is disposed on a first side of the semiconductor die and electrically connected to the first type semiconductor layer. The second electrode is disposed on a second side of the semiconductor die and electrically connected to the second type semiconductor layer. The reflective layer is disposed on the filling layer. In a top view, a first virtual line segment crossing a center of the semiconductor die intersects with an edge of the filling layer at a first point, a second virtual line segment crossing the center of the semiconductor die intersects with the edge of the filling layer at a third point. A distance between the center of the semiconductor die and the first point is different from the distance between the center of the semiconductor die and the third point.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a top schematic view of a semiconductor chip according to a first embodiment of the disclosure.

FIG. 1B is a cross-sectional schematic view of the semiconductor chip in FIG. 1A along section line I-I′.

FIG. 1C is a light emission viewing angle diagram of the semiconductor chip in FIG. 1A.

FIG. 2 is a top schematic view of a semiconductor chip according to a second embodiment of the disclosure.

FIG. 3A is a top schematic view of a semiconductor chip according to a third embodiment of the disclosure.

FIG. 3B is a light emission viewing angle diagram of the semiconductor chip in FIG. 3A.

FIG. 4 is a top schematic view of a semiconductor chip according to a fourth embodiment of the disclosure.

FIG. 5 is a top schematic view of a semiconductor chip according to a fifth embodiment of the disclosure.

FIG. 6 is a top schematic view of a semiconductor chip according to a sixth embodiment of the disclosure.

FIG. 7A is a top schematic view of a semiconductor chip according to a seventh embodiment of the disclosure.

FIG. 7B is a light emission viewing angle diagram of the semiconductor chip in FIG. 7A.

FIG. 8 is an application of an electronic device according to an embodiment of the disclosure.

### DESCRIPTION OF THE EMBODIMENTS

The disclosure may be understood with reference to the following detailed description taken in conjunction with the drawings. It should be noted that for the ease of understanding by the reader and the conciseness of the drawings, multiple drawings of the disclosure only depict a portion of an electronic device, and specific elements in the drawings may not be drawn according to actual scale. Furthermore, the number and the size of each element in the drawings are illustrative only and are not intended to limit the scope of the disclosure.

In the following specification and claims, terms such as “containing” and “including” are open-ended terms and should thus be interpreted to mean “comprising but not limited to . . . ”.

It should be understood that when an element or a film layer is referred to as being “on” or “connected to” another element or film layer, the element or film layer may be directly on the other element or film layer or directly connected to the other element or film layer, or there may be an element or a film layer inserted between the two (case of indirect connection). In contrast, when an element or a film layer is referred to as being “directly on” or “directly connected to” another element or film layer, there is no element or film layer inserted between the two.

Although terms such as “first”, “second”, and “third” may be used to describe multiple constituent elements, the constituent elements are not limited by the terms. The terms are only used to distinguish a single constituent element from other constituent elements in the specification. The claims may not use the same terms, which may be replaced by first, second, third . . . in the order of declaration of the elements in the claims. Therefore, in the following specification, a first constituent element may be a second constituent element in the claims.

In the text, the terms “about”, “approximately”, “substantially”, and “roughly” usually mean within 10%, 5%, 3%, 2%, 1%, or 0.5% of a given value or range. The number given here is an approximate number, that is, in the case where “about”, “approximately”, “substantially”, and “roughly” are not particularly described, the meanings of “about”, “approximately”, “substantially”, and “roughly” may still be implied.

In some embodiments of the disclosure, terms related to bonding and connection such as “connection” and “interconnection”, unless otherwise specified, may mean that two structures are in direct contact or may also mean that the two structures are not in direct contact, wherein there is another structure disposed between the two structures. Also, the terms related to bonding and connection may also include the case where the two structures are both movable or the two structures are both fixed. In addition, the term “coupling” includes any direct and indirect electrical connection means.

In some embodiments of the disclosure, an optical microscope (OM), a scanning electron microscope (SEM), a thin film thickness profilometer (α-step), an ellipsometer, or other suitable manners may be used to measure an area, a width, a thickness, or a height of each element or a distance or a spacing between elements. In detail, according to some embodiments, the scanning electron microscope may be used to obtain a cross-sectional structural image including the element to be measured and measure the area, the width, the thickness, or the height of each element or the distance or the spacing between the elements.

In the disclosure, the semiconductor chip may be applied in an electronic device. The electronic device may include a display device, light emitting device, backlight device, virtual reality device, augmented reality (AR) device, antenna device, sensing device, tiled device, or any combination thereof, but not limited thereto. The display device may be a non-self-luminous display or a self-luminous display according to requirements, and may be a color display or a monochrome display according to requirements. The antenna device may be a liquid crystal type antenna device or a non-liquid crystal type antenna device. The sensing device may be a device for sensing capacitance, light, thermal energy, or ultrasound. The tiled device may be a display tiled device or an antenna tiled device, but not limited thereto. The electronic components in the electronic device may include passive components and active components, such as capacitors, resistors, inductors, diodes, transistors, etc. The diode may include a light emitting diode (LED) or a photodiode. The light emitting diode may include, for example, an organic light emitting diode (OLED), a mini LED, a micro LED, or a quantum dot LED, but not limited thereto. The transistor may include, for example, a top gate thin film transistor, a bottom gate thin film transistor, or a dual gate thin film transistor, but not limited thereto. The electronic device may also include fluorescence materials, phosphor materials, quantum dot (QD) materials, or other suitable materials according to requirements, but not limited thereto. The electronic device may have peripheral systems such as driving systems, control systems, light source systems, etc. to support display devices, antenna devices, wearable devices (including augmented reality or virtual reality devices, for example), vehicle-mounted devices (including car windshields, for example), or tiled devices. It should be noted that the electronic device may be any permutation and combination of the above, but not limited thereto. The following will use the semiconductor chip in the electronic device to explain the content of the disclosure, but the disclosure is not limited thereto.

It should be noted that in the following embodiments, without departing from the spirit of the disclosure, features in several different embodiments may be replaced, reorganized, and mixed to complete other embodiments. As long as the features of the embodiments do not violate the spirit of the invention or are not conflicting, the features may be arbitrarily mixed and matched for use.

Reference will now be made in detail to the exemplary embodiments of the disclosure, and examples of the exemplary embodiments are illustrated in the drawings. Wherever possible, the same reference numerals are used in the drawings and the description to refer to the same or similar parts.

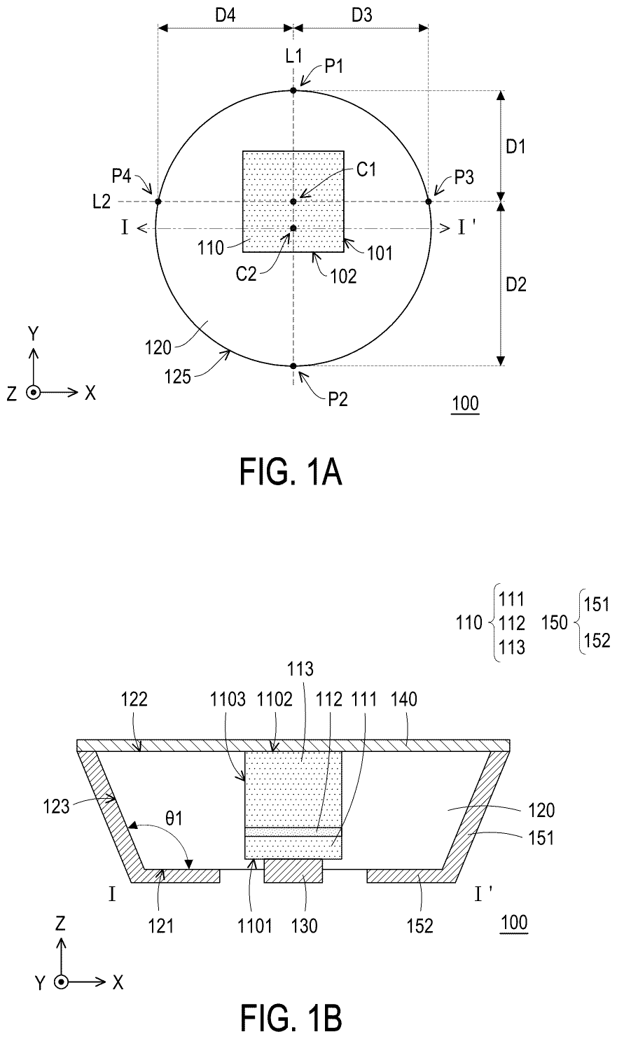

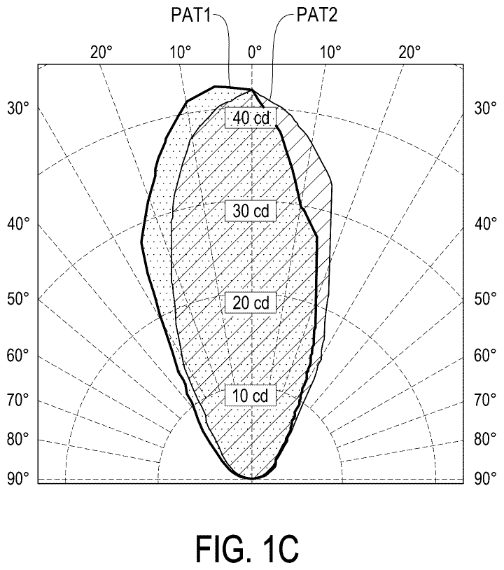

FIG. 1A is a top schematic view of a semiconductor chip according to a first embodiment of the disclosure. FIG. 1B is a cross-sectional schematic view of the semiconductor chip in FIG. 1A along section line I-I′. FIG. 1C is a light emission viewing angle diagram of the semiconductor chip in FIG. 1A. For clarity of the drawings and convenience of description, some components in a semiconductor chip 100 are omitted in FIG. 1A.

Referring to FIG. 1A and FIG. 1B, the semiconductor chip 100 of the embodiment includes a semiconductor die 110, a filling layer 120, a first electrode 130, a second electrode 140, and a reflective layer 150.

Specifically, referring to FIG. 1B, the semiconductor die 110 has a first side 1101, a second side 1102, and a side surface 1103. The first side 1101 is opposite to the second side 1102, and the first side 1101 faces the first electrode 130. The second side 1102 is closer to the second electrode 140 than the first side 1101. The side surface 1103 connects the first side 1101 and the second side 1102. In the embodiment, the semiconductor die 110 may be a vertical type chip. In a direction Z (for example, a normal direction of the semiconductor chip 100), the semiconductor die 110 includes a first type semiconductor layer 111, an active layer 112, and a second type semiconductor layer 113 stacked in sequence. The first type semiconductor layer 111 is closer to the first electrode 130 than the second type semiconductor layer 113, and the active layer 112 is disposed between the first type semiconductor layer 111 and the second type semiconductor layer 113.

In the embodiment, a direction X, a direction Y, and the direction Z are different directions. For example, the direction X may be an extending direction of section line I-I′, the direction Z may be the normal direction of the semiconductor chip 100, the direction X is perpendicular to the direction Z, and both the direction X and the direction Z are perpendicular to the direction Y, but not limited thereto.

In the embodiment, the semiconductor die 110 may be a light emitting component (for example: an organic light emitting diode, a mini light emitting diode, a micro light emitting diode, or a quantum dot light emitting diode, but not limited thereto), and the active layer 112 may be a light emitting layer, a photosensitive layer, or an intrinsic layer, but not limited thereto. In the embodiment, the first type semiconductor layer 111 may be a P-type semiconductor layer, and the second type semiconductor layer 113 may be an N-type semiconductor layer, but not limited thereto. In some embodiments, the first type semiconductor layer may also be an N-type semiconductor layer, and the second type semiconductor layer may also be a P-type semiconductor layer.

Referring to FIG. 1B, the filling layer 120 surrounds the semiconductor die 110. The filling layer 120 may contact the side surface 1103 of the semiconductor die 110. The filling layer 120 has a first surface 121, a second surface 122, and a side surface 123. The first surface 121 and the second surface 122 are opposite to each other, and the first surface 121 faces the first electrode 130. The second surface 122 is closer to the second electrode 140 than the first surface 121. The side surface 123 is disposed between the first surface 121 and the second surface 122, and the side surface 123 connects the first surface 121 and the second surface 122. In the embodiment, an angle θ1 between the side surface 123 and the first surface 121 has a taper angle, and the angle θ1 may be between 90 degrees and 150 degrees, between 100 degrees and 170 degrees, between 110 degrees and 150 degrees, or between 120 degrees and 160 degrees, to enable the filling layer 120 to be a bowl-like structure. Thereby, the filling layer 120 may work with the reflective layer 150 to concentrate the light emission of the semiconductor die 110, reduce the light emission angle of the semiconductor die 110, or improve the light emission efficiency of the semiconductor die 110, but not limited thereto. In the embodiment, the material of the filling layer 120 may include acrylic, epoxy, siloxane, silica, other transparent filling materials, or a combination thereof, but not limited thereto.

Referring to FIG. 1A, in the top view of the semiconductor chip 100, a profile of the semiconductor die 110 may be square, and a profile of the filling layer 120 may be circular, but not limited thereto. In other words, in the top view of the semiconductor chip 100, lengths of two adjacent sides (that is, a side 101 and a side 102) of the semiconductor die 110 are equal. In some embodiments not shown, the profile of the semiconductor die may also be other shapes, for example, rectangular, hexagonal, circular, or elliptical. In some embodiments not shown, the profile of the filling layer may also be other shapes, for example, elliptical.

Referring to FIG. 1A, in the top view of the semiconductor chip 100, the semiconductor die 110 has a center C1, the filling layer 120 has a center C2, and the center C1 of the semiconductor die 110 does not overlap with the center C2 of the filling layer 120 in the direction Z. Specifically, in the top view of the semiconductor chip 100, a first virtual line segment L1 may cross the center C1 of the semiconductor die 110 and intersect with an edge 125 of the filling layer 120 at a first point P1 and a second point P2, a second virtual line segment L2 may cross the center C1 of the semiconductor die 110 and intersect with the edge 125 of the filling layer 120 at a third point P3 and a fourth point P4, and the second virtual line segment L2 may be perpendicular to the first virtual line segment L1. In the embodiment, the first virtual line segment L1 may be substantially parallel to the direction Y, and the second virtual line segment L2 may be substantially parallel to the direction X, but not limited thereto.

In the embodiment, a position of the center C1 of the semiconductor die 110 may be offset relative to a position of the center C2 of the filling layer 120. Specifically, in the top view of the semiconductor chip 100, a distance D1 between the center C1 of the semiconductor die 110 and the first point P1 may be different from a distance D2 between the center C1 of the semiconductor die 110 and the second point P2, and a distance D3 between the center C1 of the semiconductor die 110 and the third point P3 may be substantially the same as a distance D4 between the center C1 of the semiconductor die 110 and the fourth point P4, but not limited thereto. In the embodiment, the distance D1 is, for example, the minimum distance measured along the direction Y between the center C1 and the first point P1; the distance D2 is, for example, the minimum distance measured along the direction Y between the center C1 and the second point P2; the distance D3 is, for example, the minimum distance measured along the direction X between the center C1 and the third point P3; and the distance D4 is, for example, the minimum distance measured along the direction X between the center C1 and the fourth point P4.

In the embodiment, the distance D2 may be greater than the distance D1 (that is, D1<D2), and a ratio of the distance D2 to the distance D1 may be greater than 1 and less than or equal to 2 (that is, 1<D2/D1≤2), but not limited thereto. In some embodiment, the difference between the distance D2 and the distance D1 is greater than 0 μm and less than or equal to 50 μm. Or, the difference may be greater than 0 μm and less than or equal to 30 μm. Or, the difference may be greater than 0 μm and less than or equal to 10 μm.

Referring to FIG. 1B, the first electrode 130 is disposed on the first side 1101 of the semiconductor die 110. The first electrode 130 may be electrically connected to the first type semiconductor layer 111 of the semiconductor die 110. In some embodiments, there is an ohmic contact layer (not shown) between the first electrode 130 and the first type semiconductor layer 111, and the ohmic contact layer may include transparent conductive oxides (TCO). In the embodiment, the material of the first electrode 130 may include conductive material with high reflective properties, so that the first electrode 130 may be used to concentrate the light emission of the semiconductor die 110, reduce the light emission angle of the semiconductor die 110, or improve the light emission efficiency of the semiconductor die 110.

Referring to FIG. 1B, the second electrode 140 is disposed on the second side 1102 of the semiconductor die 110 and the second surface 122 of the filling layer 120. The second electrode 140 may connect to the reflective layer 150. The second electrode 140 may be electrically connected to the second type semiconductor layer 113 of the semiconductor die 110. In some embodiments, there is an ohmic contact layer (not shown) between the second electrode 140 and the second type semiconductor layer 113, and the ohmic contact layer may include transparent conductive oxides. In the embodiment, the material of the second electrode 140 may include conductive material, and the conductive material may include metal oxide, graphene, metal, other suitable conductive materials, or a combination thereof, but not limited thereto. The metal oxide may include indium tin oxide (ITO), indium zinc oxide (IZO), aluminum tin oxide, aluminum zinc oxide, indium germanium zinc oxide, or other metal oxides. Alternatively, the conductive material may include thin metal or metal grid. For example, a thin metal layer (for example, magnesium layer or silver layer) may be formed, or a metal grid layer with light-transmitting openings may be formed by screen printing or other patterning processes, allowing light to penetrate the second electrode. In some embodiments, the second electrode 140 may include transparent conductive material.

Referring to FIG. 1B, the reflective layer 150 is disposed on the filling layer 120, and the reflective layer 150 is separated from the first electrode 130. The reflective layer 150 includes a first part 151 and a second part 152. The first part 151 is disposed on the side surface 123 of the filling layer 120, and the second part 152 is disposed on the first surface 121 of the filling layer 120. One side of the first part 151 may connect the second electrode 140, and the other side of the first part 151 may connect the second part 152; thereby enabling the second part 152 to be electrically connected to the second type semiconductor layer 113 of the semiconductor die 110 through the first part 151 and the second electrode 140. In the embodiment, the material of the reflective layer 150 may include conductive material with high reflective properties, such that the reflective layer 150 may concentrate the light emission of the semiconductor die 110, reduce the light emission angle of the semiconductor die 110, or improve the light emission efficiency of the semiconductor die 110. In the embodiment, the material of the reflective layer 150 may include silver, aluminum, tin, indium, gold, or a combination thereof, but not limited thereto.

In the embodiment, the first type semiconductor layer 111 and the second type semiconductor layer 113 of the vertical semiconductor die 110 may be electrically connected to the first electrode 130 and the second part 152 of the reflective layer 150 respectively, and the first electrode 130 and the second part 152 may be disposed on the same side (or disposed on the same horizontal plane) of the semiconductor chip 100, so the semiconductor chip 100 may be a vertical embedded flip-chip (VEFC) and the semiconductor chip 100 may be easily detected and mass transferred. In some embodiment, a width of the semiconductor die 110 may range from 1 to 10 micrometers, and a width of the semiconductor chip 100 may range from 10 to 50 micrometers. In some embodiments, a projection area of the first electrode 130 and the second part 152 on an X-Y plane is greater than a projection area of the semiconductor die 110 on the same X-Y plane, which facilitates the subsequent bonding process of the semiconductor chip 100.

Referring to FIG. 1C, in the light emission viewing angle diagram of the semiconductor chip 100, longitude lines indicate as angle of the viewing angle, and a unit of the angle is degree (°); latitude lines indicate as light intensity, and a unit of the light intensity is candela (cd); a pattern PAT1 is the light emission situation or the light emission pattern of the semiconductor chip 100 observed in the direction Y, and a pattern PAT2 is the light emission situation or the light emission pattern of the semiconductor chip 100 observed in the direction X.

In detail, referring to FIG. 1B and FIG. 1C simultaneously, since the distance D1 is different from the distance D2, the light emission pattern of the pattern PAT1 is asymmetrical when a front viewing angle (0 degree viewing angle) is used as symmetry axis; wherein, in the pattern PAT1, the maximum light intensity does not occur at the front viewing angle but occurs at a side viewing angle (for example, at about 10 degree viewing angle). Furthermore, since the distance D3 is approximately equal to the distance D4, the light emission pattern of the pattern PAT2 is symmetrical when the front viewing angle (0 degree viewing angle) is used as the symmetry axis; wherein, in the pattern PAT2, the maximum light intensity occurs at the front viewing angle rather than at the side viewing angle.

Accordingly, when the distance D1 between the center C1 of the semiconductor die 110 and the first point P1 is different from the distance D2 between the center C1 of the semiconductor die 110 and the second point P2 (or when the position of the center C1 of the semiconductor die 110 is offset relative to the position of the center C2 of the filling layer 120), the light emission pattern of the semiconductor chip 100 may be changed (that is, the pattern PAT1 is different from the pattern PAT2), so that the electronic device containing the semiconductor chip 100 may have better light intensity or brightness at a specific viewing angle.

Other embodiments will be listed below as illustrations. It must be noted here that the following embodiments continue to use the reference numerals and some content of the foregoing embodiments, wherein the same numerals are adopted to represent the same or similar elements, and the description of the same technical content is omitted. For the description of the omitted part, reference may be made to the foregoing embodiments and will not be repeated in the following embodiments.

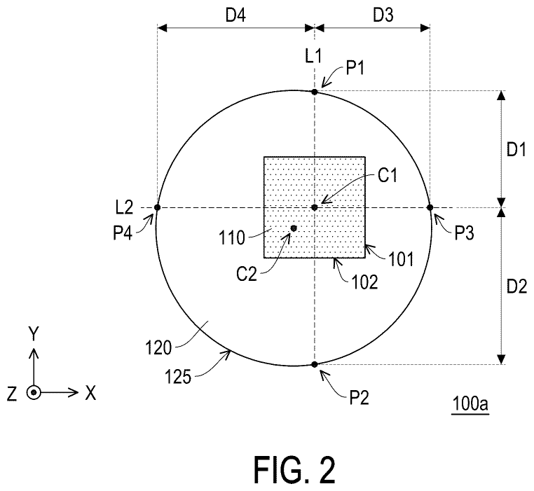

FIG. 2 is a top schematic view of a semiconductor chip according to a second embodiment of the disclosure. Please refer to FIG. 2 and FIG. 1A at the same time. A semiconductor chip 100a of the embodiment is similar to the semiconductor chip 100 in FIG. 1A. The only difference between the two is that in a top view of the semiconductor chip 100a of the embodiment, the distance D3 between the center C1 of the semiconductor die 110a and the third point P3 is different from the distance D4 between the center C1 of the semiconductor die 110a and the fourth point P4. In the embodiment, the distance D4 may be greater than the distance D3 (that is, D3<D4), and a ratio of the distance D4 to the distance D3 may be greater than 1 and less than or equal to 2 (that is, 1<D4/D3≤2), but not limited thereto. In some embodiment, the difference between the distance D4 and the distance D3 is greater than 0 μm and less than or equal to 50 μm. Or, the difference may be greater than 0 μm and less than or equal to 30 μm. Or, the difference may be greater than 0 μm and less than or equal to 10 μm.

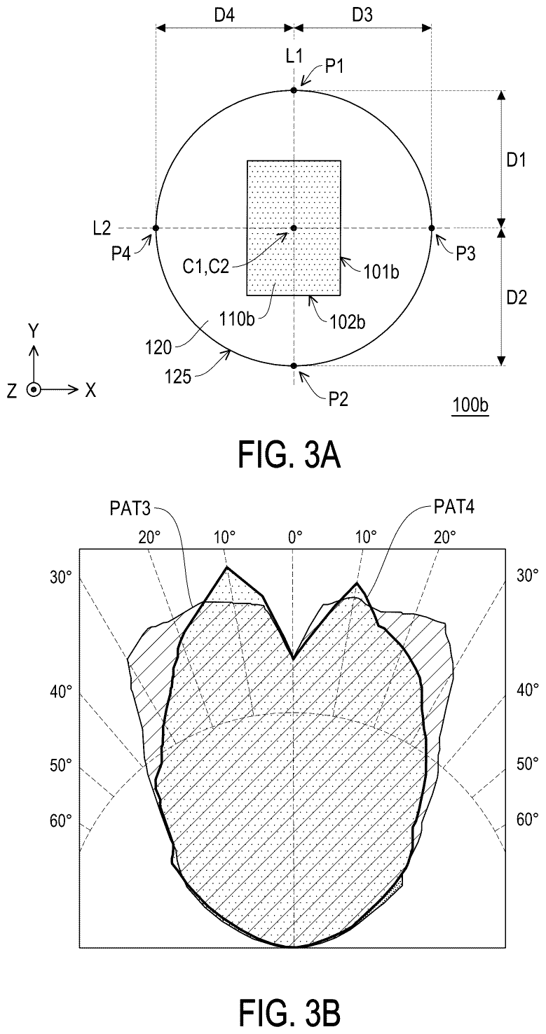

FIG. 3A is a top schematic view of a semiconductor chip according to a third embodiment of the disclosure. FIG. 3B is a light emission viewing angle diagram of the semiconductor chip in FIG. 3A. Please refer to FIG. 3A to FIG. 3B as well as FIG. 1A to FIG. 1C at the same time. A semiconductor chip 100b of the embodiment is similar to the semiconductor chip 100 in FIG. 1A. The only difference between the two is that in a top view of the semiconductor chip 100b of the embodiment, a profile of the semiconductor die 110b is rectangular, and the center C1 of the semiconductor die 110b overlaps with the center C2 of the filling layer 120 in the Z direction.

Specifically, referring to FIG. 3A, in the top view of the semiconductor chip 100b, the distance D1 between the center C1 of the semiconductor die 110b and the first point P1 is approximately the same as the distance D2 between the center C1 of the semiconductor die 110b and the second point P2, and the distance D3 between the center C1 of the semiconductor die 110b and the third point P3 is approximately the same as the distance D4 between the center C1 of the semiconductor die 110b and the fourth point P4.

In the embodiment, in the top view of the semiconductor chip 100b, the lengths of two adjacent sides (that is, the side 101b and the side 102b) of the semiconductor die 110b are different. Among them, the side 101b may be a long side of the rectangle and may be approximately parallel to the Y direction, the side 102b may be a short side of the rectangle and may be approximately parallel to the X direction, and the length of the side 101b may be greater than the length of the side 102b, but not limited thereto.

Referring to FIG. 3B, a pattern PAT3 is the light emission situation or the light emission pattern of the semiconductor chip 100b observed in the Y direction, and a pattern PAT4 is the light emission situation or the light emission pattern of the semiconductor chip 100b observed in the X direction.

In detail, referring to FIG. 3A and FIG. 3B simultaneously, since the distance D1 is approximately the same as the distance D2, and the distance D3 is approximately the same as the distance D4, the light emission pattern of the pattern PAT3 and the pattern PAT4 are both symmetrical when the front viewing angle (0 degree viewing angle) is used as the symmetry axis. Moreover, the maximum light intensity of both the pattern PAT3 and the pattern PAT4 does not occur at the front viewing angle but occurs at the side viewing angle. Since the profile of the semiconductor die 110b is rectangular, the maximum light intensity of the pattern PAT3 and the pattern PAT4 occurs at about 10 to 30 degrees viewing angle and about 10 degrees viewing angle, respectively.

Accordingly, when the lengths of the adjacent sides 101b and 102b of the semiconductor die 110b are different, the light emission pattern of the semiconductor chip 100b may be changed (that is, the pattern PAT3 is different from the pattern PAT4), so that the electronic device containing the semiconductor chip 100b may have better light intensity or brightness at a specific viewing angle.

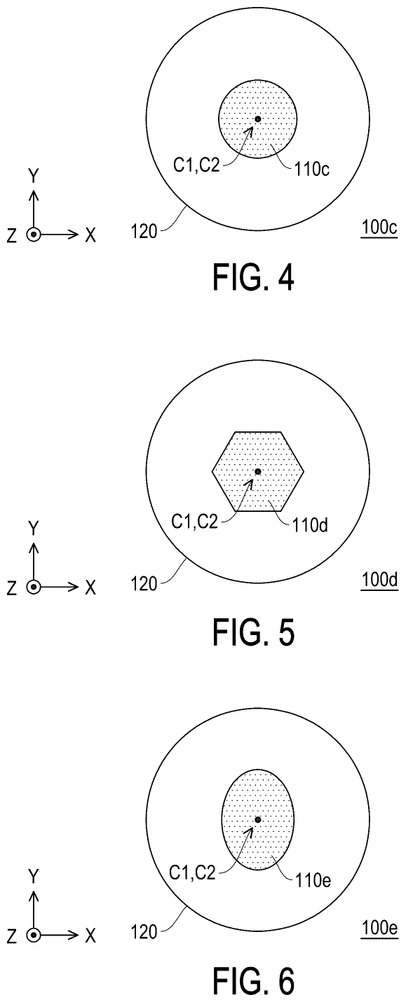

FIG. 4 is a top schematic view of a semiconductor chip according to a fourth embodiment of the disclosure. Please refer to FIG. 4 and FIG. 3 at the same time. A semiconductor chip 100c of the embodiment is similar to the semiconductor chip 100b in FIG. 3. The only difference between the two is that in a top view of the semiconductor chip 100c of the embodiment, the profile of the semiconductor die 110c is circular.

FIG. 5 is a top schematic view of a semiconductor chip according to a fifth embodiment of the disclosure. Please refer to FIG. 5 and FIG. 3 at the same time. A semiconductor chip 100d of the embodiment is similar to the semiconductor chip 100b in FIG. 3. The only difference between the two is that in a top view of the semiconductor chip 100d of the embodiment, the profile of the semiconductor die 110d is hexagonal.

FIG. 6 is a top schematic view of a semiconductor chip according to a sixth embodiment of the disclosure. Please refer to FIG. 6 and FIG. 3 at the same time. A semiconductor chip 100e of the embodiment is similar to the semiconductor chip 100b in FIG. 3. The only difference between the two is that in a top view of the semiconductor chip 100e of the embodiment, the profile of the semiconductor die 110e is elliptical.

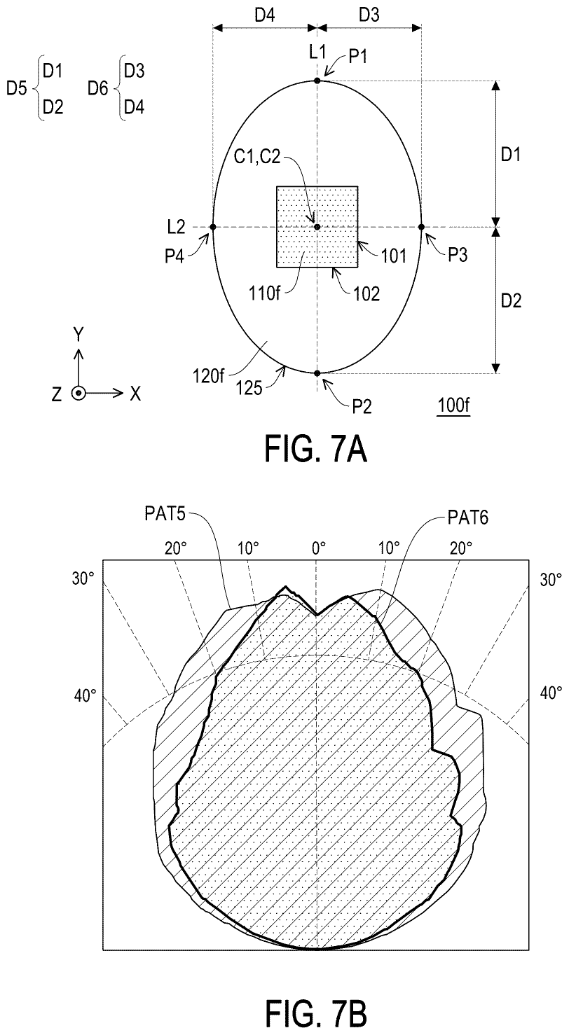

FIG. 7A is a top schematic view of a semiconductor chip according to a seventh embodiment of the disclosure. FIG. 7B is a light emission viewing angle diagram of the semiconductor chip in FIG. 7A. Please refer to FIG. 7A to FIG. 7B as well as FIG. 3A to FIG. 3B at the same time. A semiconductor chip 100f of the embodiment is similar to the semiconductor chip 100b in FIG. 3A. The only difference between the two is that in a top view of the semiconductor chip 100f of the embodiment, the profile of the semiconductor die 110f is square, and the profile of the filling layer 120f is elliptical.

Specifically, referring to FIG. 7A, since the profile of the filling layer 120f is elliptical, a sum D5 of the distance D1 and the distance D2 (that is, a length of the filling layer 120f measured along the direction Y) is different from a sum D6 of the distance D3 and the distance D4 (that is, a length of the filling layer 120f measured along the direction X). In other words, although the center C1 of the semiconductor die 110f may overlap with the center C2 of the filling layer 120f in the direction Z, the distance D1 between the center C1 of the semiconductor die 110f and the first point P1 is different from the distance D3 between the center C1 of the semiconductor die 110f and the third point P3 (or different from the distance D4 between the center C1 of the semiconductor die 110f and the fourth point P4) because the profile of the filling layer 120f is elliptical.

In the embodiment, the distance D1 may be greater than the distance D3 (that is, D3<D1), the distance D2 may be greater than the distance D4 (that is, D4<D2), the ratio of the distance D1 to the distance D3 may be greater than 1 and less than or equal to 3 (that is, 1<D1/D3≤3), the ratio of the distance D2 to the distance D4 may be greater than 1 and less than or equal to 3 (that is, 1<D2/D4≤3), and the ratio of the sum D5 to the sum D6 may be greater than 1 and less than or equal to 3 (that is, 1<D5/D6≤3), but not limited thereto. Furthermore, in the embodiment, since the center C1 of the semiconductor die 110f may overlap with the center C2 of the filling layer 120f in the direction Z, the distance D1 is equal to the distance D2, and the distance D3 is equal to the distance D4, but not limited thereto.

Referring to FIG. 7B, a pattern PAT5 is the light emission situation or the light emission pattern of the semiconductor chip 100f observed in the direction Y, and a pattern PAT6 is the light emission situation or the light emission pattern of the semiconductor chip 100f observed in the direction X.

In detail, referring to FIG. 7A and FIG. 7B simultaneously, since the distance D1 is approximately the same as the distance D2, and the distance D3 is approximately the same as the distance D4, the light emission patterns of the pattern PAT5 and the pattern PAT6 are both symmetrical when the front viewing angle (0 degree viewing angle) is used as the symmetry axis. Furthermore, the maximum light intensity of both the pattern PAT5 and the pattern PAT6 does not occur at the front viewing angle but occurs at the side viewing angle. Since the profile of the filling layer 120f is elliptical, the maximum light intensity of the pattern PAT5 and the pattern PAT6 occur at about 15 degrees viewing angle and about 5 degrees viewing angle, respectively.

Accordingly, when the distance D1 between the center C1 of the semiconductor die 110f and the first point P1 is different from the distance D3 between the center C1 of the semiconductor die 110f and the third point P3 (or when the length of the filling layer 120f measured along the direction Y is different from the length of the filling layer 120f measured along the direction X), the light emission pattern of the semiconductor chip 100f may be changed (that is, the pattern PAT5 is different from the pattern PAT6), so that the electronic device containing the semiconductor chip 100f may have better light intensity or brightness at a specific viewing angle, or the electronic device containing the semiconductor chip 100f may have different viewing angle ranges in different viewing directions.

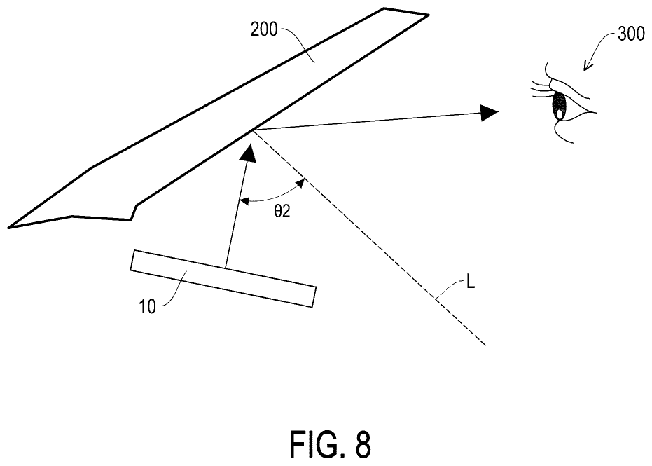

FIG. 8 is an application of an electronic device according to an embodiment of the disclosure. Referring to FIG. 8, an electronic device 10 of the embodiment may be a head-up display (HUD) or panoramic head-up display (PHUD) for vehicles, but not limited thereto.

In the embodiment, the electronic device 10 may include the semiconductor chip 100 as shown in FIG. 1A to FIG. 1B, the semiconductor chip 100a as shown in FIG. 2, the semiconductor chip 100b as shown in FIG. 3A, the semiconductor chip 100c as shown in FIG. 4, the semiconductor chip 100d as shown in FIG. 5, the semiconductor chip 100e as shown in FIG. 6, or the semiconductor chip 100f as shown in FIG. 7A, thereby providing better light intensity or brightness at specific viewing angles, providing highly concentrated light, providing high brightness light, or reducing the influence of external ambient light.

In the embodiment, relative to a normal line L of a windshield 200, an image of the electronic device 10 may be projected onto the windshield 200 at an incident angle θ2 of, for example, 30 degrees to 70 degrees, so that a driver 300 may see the image of the electronic device 10 on the windshield 200.

In summary, in the semiconductor chip of the embodiments of the disclosure, by making the distance between the center of the semiconductor die and the first point different from the distance between the center of the semiconductor die and the second point, making the lengths of adjacent sides of the semiconductor die different, or making the distance between the center of the semiconductor die and the first point different from the distance between the center of the semiconductor die and the third point, the light emission pattern of the semiconductor chip may be changed, so that the electronic device containing the semiconductor chip may have better light intensity or brightness at specific viewing angles.

Finally, it should be noted that the above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure.

What is claimed is:

1. A semiconductor chip, comprising:
a semiconductor die, comprising a first type semiconductor layer, an active layer, and a second type semiconductor layer stacked in sequence;
a filling layer, surrounding the semiconductor die;
a first electrode, disposed on a first side of the semiconductor die and electrically connected to the first type semiconductor layer;
a second electrode, disposed on a second side of the semiconductor die and electrically connected to the second type semiconductor layer; and
a reflective layer, disposed on the filling layer,
wherein in a top view, a first virtual line segment crossing a center of the semiconductor die intersects with an edge of the filling layer at a first point and a second point, and a first distance between the center of the semiconductor die and the first point is different from a second distance between the center of the semiconductor die and the second point.

2. The semiconductor chip according to claim 1, wherein the second distance is greater than the first distance.

3. The semiconductor chip according to claim 2, wherein a ratio of the second distance to the first distance is greater than 1 and less than or equal to 2.

4. The semiconductor chip according to claim 1, wherein in the top view, a second virtual line segment crossing the center of the semiconductor die intersects with the edge of the filling layer at a third point and a fourth point, the second virtual line segment is perpendicular to the first virtual line segment, and a third distance between the center of the semiconductor die and the third point is substantially the same as a fourth distance between the center of the semiconductor die and the fourth point.

5. The semiconductor chip according to claim 1, wherein in the top view, a second virtual line segment crossing the center of the semiconductor die intersects with the edge of the filling layer at a third point and a fourth point, the second virtual line segment is perpendicular to the first virtual line segment, and a third distance between the center of the semiconductor die and the third point is different from a fourth distance between the center of the semiconductor die and the fourth point.

6. The semiconductor chip according to claim 5, wherein the fourth distance is greater than the third distance.

7. The semiconductor chip according to claim 6, wherein a ratio of the fourth distance to the third distance is greater than 1 and less than or equal to 2.

8. The semiconductor chip according to claim 1, wherein in the top view, a profile of the semiconductor die is square, rectangular, hexagonal, circular or elliptical.

9. The semiconductor chip according to claim 1, wherein in the top view, a profile of the filling layer is circular or elliptical.

10. The semiconductor chip according to claim 1, wherein the center of the semiconductor die does not overlap with a center of the filling layer.

11. The semiconductor chip according to claim 1, wherein the filling layer has a first surface, a second surface and a side surface, the first surface and the second surface are opposite to each other, the side surface connects the first surface and the second surface, and an angle between the side surface and the first surface is between 90 degrees and 150 degrees.

12. The semiconductor chip according to claim 11, wherein the angle is between 110 degrees and 150 degrees.

13. The semiconductor chip according to claim 1, wherein the semiconductor chip is a vertical embedded flip-chip.

14. A semiconductor chip, comprising:
a semiconductor die, comprising a first type semiconductor layer, an active layer, and a second type semiconductor layer stacked in sequence;
a filling layer, surrounding the semiconductor die;
a first electrode, disposed on a first side of the semiconductor die and electrically connected to the first type semiconductor layer;
a second electrode, disposed on a second side of the semiconductor die and electrically connected to the second type semiconductor layer; and
a reflective layer, disposed on the filling layer,
wherein in a top view, a first virtual line segment crossing a center of the semiconductor die intersects with an edge of the filling layer at a first point, a second virtual line segment crossing the center of the semiconductor die intersects with the edge of the filling layer at a third point, and a first distance between the center of the semiconductor die and the first point is different from a third distance between the center of the semiconductor die and the third point.

15. The semiconductor chip according to claim 14, wherein the first distance is greater than the third distance.

16. The semiconductor chip according to claim 15, wherein a ratio of the first distance to the third distance is greater than 1 and less than or equal to 3.

17. The semiconductor chip according to claim 14, wherein in the top view, lengths of two adjacent sides of the semiconductor die are different.

18. The semiconductor chip according to claim 14, wherein in the top view, a profile of the semiconductor die is square, rectangular, hexagonal, circular or elliptical.

19. The semiconductor chip according to claim 14, wherein in the top view, a profile of the filling layer is elliptical.

20. The semiconductor chip according to claim 14, wherein the center of the semiconductor die overlaps with a center of the filling layer.
